(19) United States
(12) Patent Application Publication
(10) Pub. No.: US 2025/0340055 A1
(43) Pub. Date: Nov. 6, 2025

(54) SCREEN PRINTING DEVICE

(71) Applicant: Samsung Display Co., LTD., Yongin-si (KR)

(72) Inventors: Hyun Ho JEONG, Yongin-si (KR); Dong Ho KIM, Yongin-si (KR); Ju Suk OH, Yongin-si (KR)

(21) Appl. No.: 18/961,466

(22) Filed: Nov. 27, 2024

(30) Foreign Application Priority Data
May 3, 2024 (KR) 10-2024-0059019

(51) Int. Cl. B41F 15/36; B41F 15/08; B41F 15/22; G02B 5/00

(52) U.S. Cl. CPC B41F 15/36; B41F 15/0818; B41F 15/22; G02B 5/003; B41P 2215/12; B41P 2215/50

(57) ABSTRACT

A screen printing device includes a substrate support unit, a squeegee member above the substrate support unit, a screen mask unit disposed between the substrate support unit and the squeegee member, the screen mask unit defining a printing opening for forming a printed pattern, and at least one tension adjusting member disposed on a first surface of the screen mask unit facing the substrate support unit and adjacent to the printing opening.

This application claims priority to Korean Patent Application No. 10-2024-0059019, filed on May 3, 2024, and all the benefits accruing therefrom under 35 U.S.C. § 119, the content of which in its entirety is herein incorporated by reference.

### BACKGROUND

### 1. Field

The disclosure relates to a screen printing device.

### 2. Description of the Related Art

As the information society advances, the demand for display devices to display images is increasing in various forms. For example, the display devices are applied in various electronic devices such as smartphones, digital cameras, laptop computers, navigation systems, and smart televisions (“TVs”).

As the display devices, several types of the display devices such as liquid crystal displays (“LCDs”) and organic light-emitting displays are being used. Among these, organic light-emitting displays display images using organic light-emitting elements that generate light through the recombination of electrons and holes. Organic light-emitting displays include a plurality of transistors that provide driving current to the organic light-emitting elements.

Various wiring and components are arranged in the non-display areas of the display devices, and light-shielding portions may be arranged to prevent them from being visible from the outside.

To prevent light leakage in the non-display areas of such display devices, research is actively being conducted on printing devices that print light-shielding portions on cover glass and methods for manufacturing cover glass.

One exemplary printing method is screen printing, which is a process where ink is filled into the mesh openings by utilizing the tension applied to a screen mesh during the movement of a squeegee and a screen mask and a substrate simultaneously come into line contact, transferring the filled ink. In other words, screen printing is a process of applying ink to the substrate by utilizing viscoelastic changes in the ink during process.

Specifically, in screen printing, ink is filled through the openings of the screen mask using the squeegee on the substrate, and then the screen mask is removed to print an ink pattern on the substrate.

### SUMMARY

During such printing, pattern defects in the edge areas of print, such as saw-tooth-shaped pattern defects, may occur due to the squeegee's operating direction and the mesh shape. This is because printing defects, such as saw-tooth patterns, may strongly occur in the edge areas of the print along the squeegee's operating direction and pressure direction. Therefore, it is desired to minimize the impact of such printing defects.

Features of the disclosure provide a screen printing device that may prevent defects in a printed pattern.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, there is provided a screen printing device including: a substrate support unit; a squeegee member above the substrate support unit; a screen mask unit disposed between the substrate support unit and the squeegee member, the screen mask unit defining a printing opening for forming a printed pattern; and at least one tension adjusting member disposed on a first surface of the screen mask unit facing the substrate support unit and adjacent to the printing opening.

In an embodiment, the at least one tension adjusting member is provided in plural, and a plurality of tension adjusting members may form a group, creating multiple rows.

In an embodiment, the plurality of adjusting members may be arranged in the multiple rows, and multiple tension adjusting members arranged may be one row among the plurality of tension adjusting members respectively have sizes equal to each other.

In an embodiment, the at least one tension adjusting member and the printing opening each may have a quadrangular frame shape, e.g., rectangular frame shape, and the at least one tension adjusting member may be smaller in size than the printing opening and may be disposed to overlap an inside the printing opening.

In an embodiment, a height of the at least one tension adjusting member along a thickness direction of the screen mask unit may be smaller than a height of the printing opening.

In an embodiment, the screen mask unit may include a mesh member, which is porous, and a mesh cover layer, which covers the mesh member, and the mesh cover layer may cover the mesh member but expose a portion of the mesh member through the printing opening.

In an embodiment, the screen mask unit may further include a support frame, which supports edge areas of the mesh cover layer.

In an embodiment, the substrate support unit may support a substrate to be disposed below the screen mask unit, the substrate may be a cover glass, and the printed pattern printed through the printing opening of the screen mask unit may be a light-shielding printed pattern disposed along edge areas of the cover glass.

In an embodiment, the screen printing device may further include a printing unit including the squeegee member, which transfers ink onto the substrate through the printing opening; and a printing transfer unit which moves the printing unit.

In an embodiment of the disclosure, there is provided a screen printing device including: a substrate support unit; a squeegee member above the substrate support unit; a screen mask unit disposed between the substrate support unit and the squeegee member, the screen mask unit defining a printing opening for forming a printed pattern; and at least one adhesive tape attached to a first surface of the screen mask unit facing the substrate support unit and adjacent to the printing opening.

In an embodiment, the at least one adhesive tape may have a hollow quadrangular frame shape, e.g., rectangular frame shape.

In an embodiment, the at least one adhesive tape may be disposed adjacent to the printing opening, and may be attached along at least one area of the printing opening.

In an embodiment, the at least one adhesive tape is provided in plural, a plurality of adhesive tapes may be disposed in multiple rows with a spacing therebetween, and multiple adhesive tapes arranged in one row among the plurality of adhesive tapes may respectively have sizes equal to each other.

In an embodiment, the screen mask unit may include a mesh member, which is porous, and a mesh cover layer, which covers the mesh member, and the mesh cover layer may cover the mesh member but expose a portion of the mesh member through the printing opening.

In an embodiment of the disclosure, there is provided a transparent panel for a display device, including: a substrate including first and second edges, which extend in a first direction and face each other, and third and fourth edges, which extend in a second direction intersecting the first direction and face each other; and a light-shielding printed pattern disposed on a periphery of the substrate, where the light-shielding printed pattern includes a first pattern part adjacent to the first edge of the substrate and a second pattern part adjacent to the second edge of the substrate, the first and second pattern parts each extends in the first direction and includes first and second pattern edges facing each other, and the first pattern edge of the first pattern part and the second pattern edge of the first pattern part have different heights from each other.

In an embodiment, the first pattern edge of the second pattern part and the second pattern edge of the second pattern part may have different heights from each other.

In an embodiment, the second pattern edge of the first pattern part and the first pattern edge of the second pattern part may be disposed inwardly of each pattern part and face each other, the height of the second pattern edge of the first pattern part may be greater than the height of the first pattern edge of the first pattern part, and the height of the second pattern edge of the second pattern part may be greater than the height of the first pattern edge of the second pattern part.

In an embodiment, the light-shielding printed pattern may further include a third pattern part adjacent to the third edge of the substrate and a fourth pattern part adjacent to the fourth edge of the substrate.

In an embodiment, the third and fourth pattern parts each may extend in the second direction and include third and fourth pattern edges facing each other, and the third pattern edges of the third and fourth pattern parts may each have a height identical to a height of each of the fourth pattern edges of the third and fourth pattern parts.

In an embodiment, the first pattern part, the third pattern part, the second pattern part, and the fourth pattern part may be connected to one another to define a closed loop.

According to the aforementioned and other embodiments of the disclosure, it is possible to suppress the occurrence of defects in a printed pattern, specifically preventing the occurrence of a defective pattern such as saw-tooth shapes on a printed surface.

It should be noted that the effects of the disclosure are not limited to those described above, and other effects of the disclosure will be apparent from the following description.

### BRIEF DESCRIPTION OF THE DRAWINGS

The above and other advantages and features of the disclosure will become more apparent by describing in detail embodiments thereof with reference to the attached drawings, in which:

FIG. 1 is a schematic diagram of an embodiment of a screen printing device according to the disclosure;

FIG. 2 is a cross-sectional view illustrating a display device;

FIG. 3 is a perspective view of a cover glass of FIG. 2;

FIG. 4 is a plan view illustrating the arrangement of a screen mask unit, a tension adjusting member, and the cover glass of FIG. 1;

FIG. 5A is a top plan view of the screen mask unit of FIG. 1, and FIG. 5B is an enlarged view of portion AA of FIG. 5A;

FIG. 6A is a bottom rear view of the screen mask unit of FIG. 1, and FIG. 6B is an enlarged view of portion BB of FIG. 6A;

FIG. 7 is a cross-sectional view of the screen mask unit of FIG. 1;

FIGS. 8 through 12 are diagrams illustrating the process of printing ink on the cover glass by the screen mask unit;

FIG. 13A is an enlarged view of the printed pattern of FIG. 12, and FIG. 13B is an enlarged view of portion CC of FIG. 13A;

FIG. 14A is an enlarged view of a printed pattern printed by a screen mask unit without a tension adjusting member, and FIG. 14B is an enlarged view of portion DD of FIG. 14A;

FIG. 15 is a cross-sectional view of a light-shielding printed pattern and a substrate along line X-X of FIG. 3;

FIG. 16 is a cross-sectional view of the light-shielding printed pattern and the substrate along line X1-X1 of FIG. 3; and

FIGS. 17A through 24 are diagrams showing other embodiments of the screen mask unit, FIG. 17B is an enlarged view of portion EE of FIG. 17A, and FIG. 18B is an enlarged view of portion FF of FIG. 18A.

### DETAILED DESCRIPTION

Embodiments of the invention will now be described more fully hereinafter with reference to the accompanying drawings, in which preferred embodiments of the invention are shown. Embodiments of the disclosure may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it may be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

The term such as “driving unit” as used herein is intended to mean a hardware component that performs a predetermined function. The hardware component may include a circuitry such as a field-programmable gate array (“FPGA”) or an application-specific integrated circuit (“ASIC”), for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Embodiments of the disclosure will be described with reference to the attached drawings.

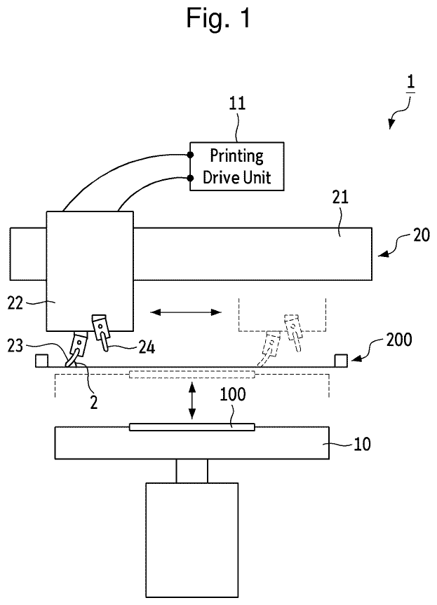

FIG. 1 is a schematic diagram of an embodiment of a screen printing device according to the disclosure.

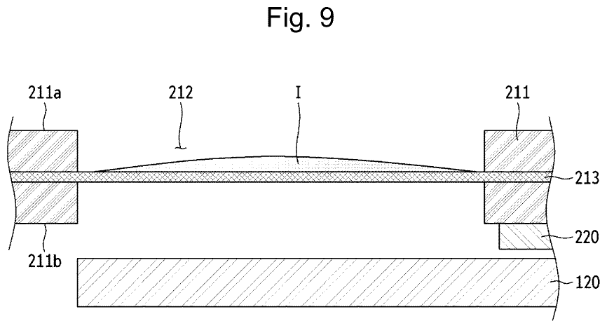

Referring to FIG. 1, a screen printing device 1 is a device that applies ink I (refer to FIG. 9) to the surface of a printing target to form a printed pattern 122. In an embodiment, the screen printing device 1 may be used in the manufacture of chip components such as capacitors, inductors, thermistors, touch panels, liquid crystal display (“LCD”) substrates, low temperature co-fired ceramics (“LTCC”) substrates, solar cell electrodes, and other electronic components, for example, but the disclosure is not limited thereto.

The screen printing device 1 prints the printed pattern 122 using a silk screen printing method, and the silk screen printing method involves transferring ink I applied to a silk screen using a squeegee member. Specifically, the formation of the printed pattern 122 through screen printing involves positioning a screen mask unit 200 with a printing opening 212 formed thereon over the substrate 100, applying the ink I to the screen mask unit 200 using a squeegee, and then removing the screen mask unit 200. After the formation of the printed pattern 122, the applied ink I may be cured, but the printing method is not limited to this sequence.

The screen printing device 1 may be used, e.g., in the manufacture of display devices. The screen printing device 1 will hereinafter be described as being applied to the manufacture of a display device, but the disclosure is not limited thereto. The screen printing device 1 may include a substrate support unit 10, which supports the substrate 100 that is a printing target, a screen mask unit 200, which is disposed on the substrate support unit 10, a printing unit 22, which is for printing the ink I on the substrate 100, and a printing transfer unit 20, which is for moving the printing unit 22. The printing unit 22 may include a scraper 23, which applies the ink I, and a squeegee member 24, which transfers the ink I. The scraper 23 may contact a horizontal surface of the substrate 100 or the screen mask unit 200 with an inclination angle, but the description is not limited thereto.

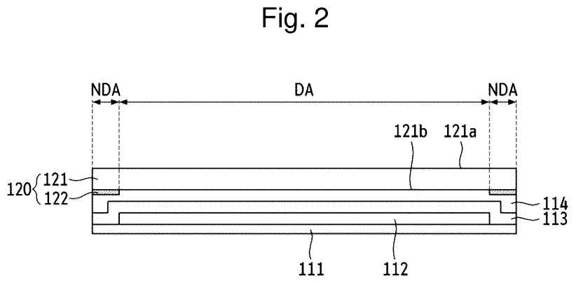

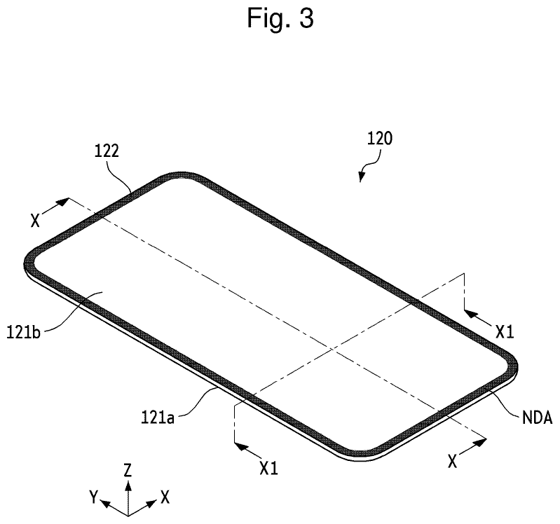

FIG. 2 is a cross-sectional view of a display device, and FIG. 3 is a perspective view of a cover glass of FIG. 2.

Referring to FIG. 2, the display device may include a display panel, and the display panel may include one or more light sources providing light. In an embodiment, the display panel may be a light-receiving panel that includes an external light source, or a self-luminous panel that includes internal light-emitting elements, for example. The self-luminous panel includes a plurality of light-emitting elements. In embodiments, the light-emitting elements include organic light-emitting diodes (“OLEDs”), quantum dot light-emitting diodes (“QLEDs”), inorganic-based micro light-emitting diodes (“micro LEDs”), and inorganic-based nano LEDs.

The display panel may include a display area DA that displays an image and a non-display area NDA that does not display an image. The non-display area NDA may be disposed around the display area DA, and the non-display area NDA may at least partially or surround an entirety of the display area DA.

Referring to FIG. 2 in an embodiment, the display device may include a display substrate 111, a display element layer 112, which is formed on the display substrate 111, a thin-film encapsulation layer 113, which protects the display element layer 112, a pressure-sensitive adhesive (“PSA”) layer 114, a cover glass 120, which is formed on top of the display element layer 112, and a light-shielding printed pattern 122, which is formed along the edges of the bottom surface 121b of the cover glass 120 to block incoming light.

The display substrate 111 may be an LCD panel including or consisting of liquid crystals or an organic light-emitting panel including or consisting of organic light-emitting elements. Additionally, the display substrate 111, which is a transparent substrate, may be a flexible substrate such as a polymer film.

The display element layer 112 is formed on the display substrate 111 and includes an element area where active elements such as thin-film transistors (“TFTs”) are formed and an emission area where a light-emitting layer is formed. The element area and the emission area may be separated from each other or may overlap.

The thin-film encapsulation layer 113 may cover and protect the display substrate 111 and the display element layer 112. The thin-film encapsulation layer 113 may be formed on the display element layer 112 and may face the display substrate 111. The thin-film encapsulation layer 113 may prevent the entry of oxygen and moisture from the outside, thereby protecting the display element layer 112.

Referring to FIGS. 2 and 3, the cover glass 120 may be formed on the thin-film encapsulation layer 113. Specifically, the cover glass 120 may be attached to the thin-film encapsulation layer 113 by the PSA layer 114, which is formed with a PSA.

The cover glass 120 may include a bottom surface 121b, which faces the thin-film encapsulation layer 113, and a top surface 121a, which is opposite the bottom surface 121b. A light-shielding printed pattern 122 may be disposed on the bottom surface 121b, but the disclosure is not limited thereto. In an alternative embodiment, the light-shielding printed pattern 122 may be disposed on the top surface 121a.

The cover glass 120 may be disposed on one surface, in the Z-axis direction, of the

display panel, such as the top surface of the display panel, and may cover and protect the display panel. In an embodiment, the cover glass 120 may have the same shape as that of the display panel but may be larger in size to fully cover one surface of the display panel, for example. In other words, the sides of the cover glass 120 may extend beyond the corresponding sides of the display panel, but the disclosure is not limited thereto.

The cover glass 120 may be quadrangular, e.g., rectangular in shape when viewed from above. In an embodiment, as illustrated in FIG. 3, the cover glass 120 may have a quadrangular, e.g., rectangular plane shape with shorter sides in the X-axis direction and longer sides in the Y-axis direction, for example. The corners where the shorter sides in the X-axis direction and the longer sides in the Y-axis direction meet may be formed at right angles or rounded with a curvature. However, the plane shape of the cover glass 120 is not particularly limited, and the cover glass 120 may be formed in another polygonal shape, a circular shape, or an elliptical shape.

The cover glass 120 is illustrated as being flat, but the disclosure is not limited thereto. In an alternative embodiment, at least one side of the cover glass 120 may be curved with a predetermined curvature.

The cover glass 120 may include a base substrate 121 and a light-shielding printed pattern 122, which is disposed on at least a part of the base substrate 121. The base substrate 121 may include or consist of a transparent material that may transmit

light, but the disclosure is not limited thereto. In an embodiment, the base substrate 121 may include glass, sapphire, quartz, or a transparent plastic film, for example. When the base substrate 121 includes a plastic material, the cover glass 120 may have flexible properties.

When the base substrate 121 is a plastic film, embodiments of the plastic material include, but are not limited to, polyimide, polyacrylate, polycarbonate, polyvinylidene chloride, polyvinylidene difluoride, polyethylene naphthalate, polystyrene, ethylene vinyl alcohol copolymer, polyethersulfone, cellulose acetate propionate, polyetherimide, polyphenylene sulfide, polyarylate, tri-acetyl cellulose, polymethyl methacrylate, or polyethylene terephthalate (“PET”).

The base substrate 121 may have a quadrangular parallelepiped shape, e.g., rectangular parallelepiped shape, but the disclosure is not limited thereto. That is, the base substrate 121 may have various other shapes depending on the shape of the display panel.

The base substrate 121 may have substantially the same shape as that of the display panel, but the disclosure is not limited thereto. The shape of the base substrate 121 is not particularly limited as long as it may fully cover the display panel. In an embodiment, the base substrate 121 may have a quadrangular plane shape, e.g., rectangular plane shape, specifically with vertical corners or rounded corners, for example.

The light-shielding printed pattern 122 may be disposed on the bottom surface 121b of the cover glass 120, which is the inner surface of the base substrate 121, that is, the surface facing the display panel.

The light-shielding printed pattern 122 is formed on the edge portions of the bottom surface 121b of the cover glass 120, i.e., in a bezel area, which is the non-display area NDA. Thus, the light-shielding printed pattern 122 may be disposed in the non-display area NDA of the cover glass 120, preventing light leakage in the display device and adding color to the bezel area of the display device.

The light-shielding printed pattern 122 may be an ink printing layer printed with ink I that has color. When formed with ink I that has color, the light-shielding printed pattern 122 may function to block incoming light from the outside. This light-shielding printed pattern 122 may be a layer formed by including a pigment or dye.

The ink I forming the light-shielding printed pattern 122 may be ink I for a black matrix and may be provided in liquid form, but the disclosure is not limited thereto. The ink I may include, e.g., a solvent and an organic material contained in the solvent. The organic material may be dispersed in the solvent. The organic material may be a solid substance remaining on the substrate 100 after the solvent is removed. The solvent may be a substance that vaporizes or volatilizes at room temperature or when heated. The solvent may include acetone, water, alcohol, toluene, etc. The ink I may be dissolved in the solvent, or may be a suspension of solid content, where the solid content may vary from an organic substance to a metallic substance. The ink I may be black ink I representing black, but the disclosure is not limited thereto. That is, various inks I may be used.

Referring to FIGS. 1 and 3, the screen printing device 1 may be a device for printing the light-shielding printed pattern 122 on the cover glass 120 of FIG. 2.

In the screen printing device 1, the substrate 100, which is the printing target, may be the cover glass 120. In this case, the screen printing device 1 may be a device for printing ink I on the periphery of the cover glass 120, specifically to form the light-shielding printed pattern 122 on the periphery of the cover glass 120. The cover glass 120 will hereinafter be described as being the substrate 100, but the disclosure is not limited thereto. That is, the screen printing device 1 may be used for various printing targets.

The substrate support unit 10 may be disposed below the substrate 100 to support the substrate 100. The substrate support unit 10 may be fixed in position to be at a predetermined distance from the printing unit 22, and may further include lifting means for adjustable height, so that when loaded on the substrate support unit 10, the substrate 100 may be raised toward the printing unit 22, and lowered when printing is complete, but the disclosure is not limited thereto.

The printing transfer unit 20 may include a slider 21, to which the printing unit 22 is coupled, and a printing drive unit 11, which moves the printing unit 22 along the slider 21.

The printing unit 22 may be slidably coupled to the slider 21, and the slider 21 may guide the movement of the printing unit 22 in the direction in which the ink I is printed on the substrate 100, e.g., in the left-right direction indicated by the arrow in FIG. 1. The printing unit 22 may be slidably coupled to the slider 21 to be movable along the slider 21, or may be fixed to the slider 21 for the slider 21 to movable left and right, but the disclosure is not limited thereto. That is, various guiding means capable of allowing for the movement of the printing unit 22 for printing may be used.

The printing drive unit 11 may provide the driving force for the printing unit 22 to move along the slider 21. In an embodiment, a driving motor may be provided, and the printing unit 22 may be moved in the arrow's direction by the driving force from the driving motor, for example. However, the disclosure is not limited to this.

The scraper 23 and the squeegee member 24 may each be coupled to the printing unit 22 at one end, with an opposite end being a free end that contacts the ink I on the substrate 100 or the screen mask unit 200. The scraper 23 and the squeegee member 24 may be rotatably coupled at a predetermined angle to the lower part of the printing unit 22, but their coupling position and method are not particularly limited as long as they are able to apply and print the ink I on the substrate 100.

The scraper 23 may spread and apply the ink I broadly onto the screen mask unit 200, disposed on the substrate 100. The squeegee member 24 transfers the ink I applied by the scraper 23 from the screen mask unit 200 to the substrate 100 to print the ink I.

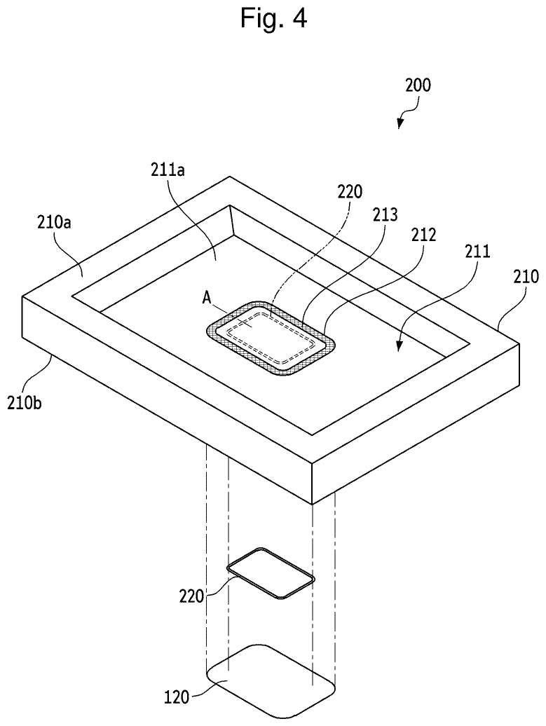

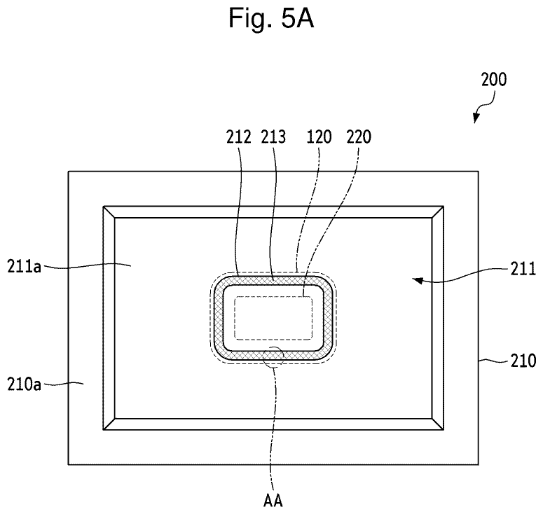

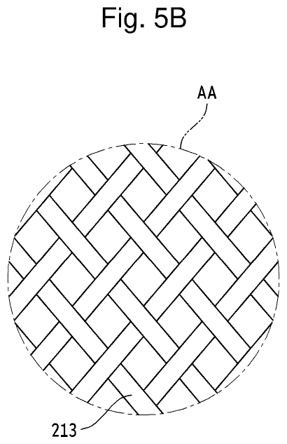

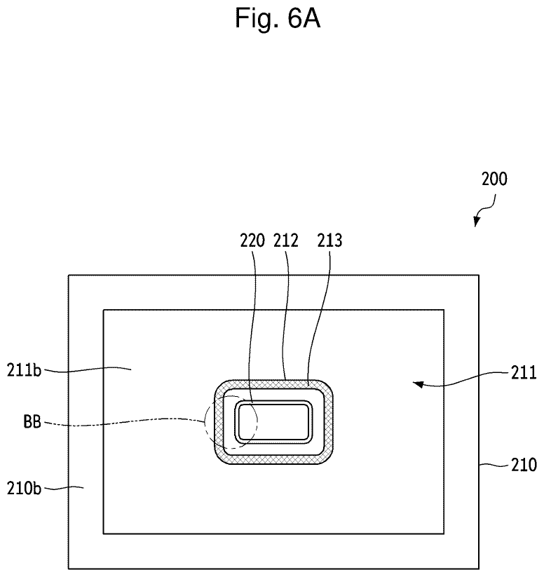

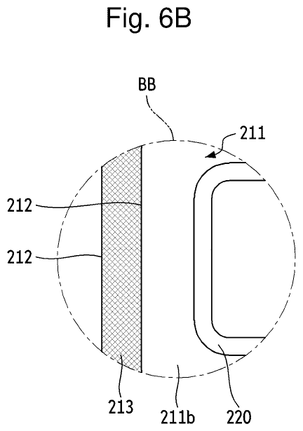

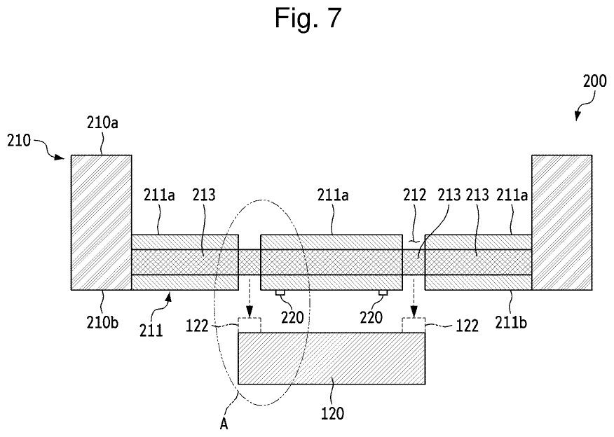

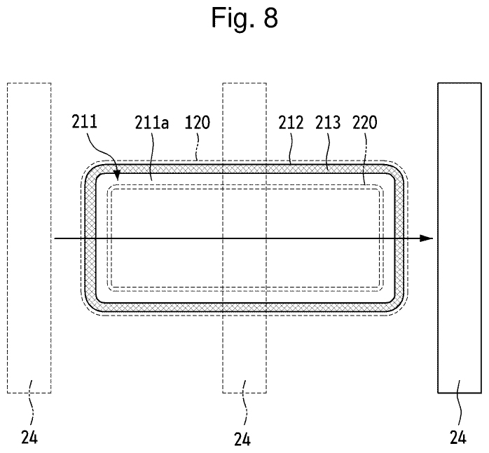

FIG. 4 is a plan view illustrating the arrangement of the screen mask unit, the tension adjusting member, and the cover glass of FIG. 1, FIG. 5A is a top plan view of the screen mask unit of FIG. 1, FIG. 5B is an enlarged view of portion AA of FIG. 5A, FIG. 6A is a bottom rear view of the screen mask unit of FIG. 1, FIG. 6B is an enlarged view of portion BB of FIG. 6A, FIG. 7 is a cross-sectional view of the screen mask unit of FIG. 1, and FIGS. 8 through 12 are diagrams illustrating the process of printing ink on the cover glass by the screen mask unit.

Referring to FIGS. 4, 5A and 5B, the screen mask unit 200 may include a support frame 210, a printing mask (211 and 213), which is coupled to the support frame 210 and has a printing opening 212, and a tension adjusting member 220, which is disposed below the printing mask (211 and 213).

The printing opening 212 is disposed at the center of the printing mask (211 and 213), allowing the printed ink I to pass through in the Z-axis direction. The ink I applied to the screen mask unit 200 passes through the printing opening 212 and serves as a passage for the ink I to be printed onto the substrate 100. Through the printing opening 212, a part of a mesh member 213 that will be described later may be exposed, allowing the ink I to pass through the printing opening 212, finally pass through the mesh member 213, and then be exposed onto the substrate 100.

The printing opening 212 corresponds to the area where the ink I passes through to be printed on the substrate 100, and may thus have the same shape as that of the light-shielding printed pattern 122 on the substrate 100. In an embodiment, as illustrated in FIG. 3, when forming the light-shielding printed pattern 122 on the edge areas of the cover glass 120, the printing opening 212 may be disposed to overlap with the area where the black light-shielding printed pattern 122 is formed on the edge perimeter areas of the cover glass 120, and may be formed in the same shape as that of the black light-shielding printed pattern 122, for example. In an embodiment, the printing opening 212 may have a quadrangular frame shape, e.g., rectangular frame shape identical to the light-shielding printed pattern 122, for example, but the disclosure is not limited thereto. That is, the printing opening 212 may have various other polygonal shapes, a circular shape, or an elliptical shape depending on the shape of the light-shielding printed pattern 122.

The support frame 210 may support the perimeter area of the printing mask (211 and 213). Specifically, the support frame 210 may be coupled with the mesh member 213 of the printing mask (211 and 213), which will be described later, and may fix the perimeter area of the mesh member 213.

The support frame 210 may include or consist of a metal or heat-resistant resin, but the disclosure is not limited thereto. That is, the support frame 210 may include or consist of various materials that provide the strength to support the printing mask (211 and 213).

The support frame 210 may have an empty quadrangular frame shape, e.g., rectangular frame shape, but the disclosure is not limited thereto. That is, the support frame 210 may have various other polygonal shapes, a circular shape, or an elliptical shape.

The support frame 210 may include an upper surface 210a, which faces the printing unit 22, and a lower surface 210b, which faces the cover glass 120. The support frame 210 may have a central area with an empty quadrangular frame shape, e.g., rectangular frame shape, with the mesh member 213 disposed to cover the central area of the support frame 210, and with the perimeter areas of the mesh member 213 fixed to the support frame 210.

Specifically, the perimeter areas of the mesh member 213 may be fixed to the support

frame 210. The perimeter areas of the mesh member 213 may be adhered to the support frame 210 using an adhesive or various fixing means, but the disclosure is not limited thereto. In an embodiment, the mesh member 213 may be coupled to the support frame 210 using synthetic rubber or acrylic adhesive, but the type of adhesive is not limited and may be varied, for example.

Referring to FIGS. 6A to 7, the printing mask (211 and 213) may include a porous mesh member 213 and a mesh cover layer 211, which is applied to the mesh member 213 to cover the mesh member 213.

The mesh member 213 may include a plurality of pores, and may transfer the ink I to the substrate 100 through the printing opening 212 by approaching or moving away from the substrate 100 when pressed by the squeegee member 24.

Specifically, the entirety of the mesh member 213 may be covered by the mesh cover layer 211. The pores of the mesh member 213 may be closed by the mesh cover layer 211, and some areas of the mesh member 213 may be exposed through the printing opening 212. The area closed by the mesh cover layer 211 corresponds to a non-printing area where the ink I does not pass, and the area exposed through the printing opening 212 corresponds to a printing area where the ink I is printed.

The mesh member 213 may be a woven fabric with warp and weft threads forming a net-like mesh, but the disclosure is not limited thereto. That is, the mesh member 213 may be in various forms as long as it has pores to pass the ink I through. Additionally, the mesh member 213 may include or consist of a material such as polyester or stainless steel (“SUS”), but the disclosure is not limited thereto. That is, the mesh member 213 may include or consist of various other materials as long as it has elasticity to be pressed by the squeegee member 24.

Thus, the mesh member 213 allows the ink I to pass through its pores exposed by the printing opening 212. Thus, as the ink 1 passes through the exposed pores in the printing opening 212, the light-shielding printed pattern 122 may be formed on the substrate 100.

The printing opening 212, which exposes a part of the mesh member 213, may be disposed in the central area of the mesh cover layer 211, in the same shape as that of the light-shielding printed pattern 122.

When the printing opening 212, which exposes a part of the mesh member 213, is disposed in the mesh cover layer 211, the printing opening 212 may be formed by exposing and removing a part of the mesh cover layer 211 during its formation. Specifically, a coating solution for forming the mesh cover layer 211 may be applied to cover the entirety of the mesh member 213, and after the application of the coating solution is complete, a part of the mesh cover layer 211 may be removed by exposure to form the printing opening 212, allowing the ink I to penetrate the printing opening 212. As a part of the mesh cover layer 211 is removed, the printing opening 212, which exposes a part of the mesh member 213, may be formed in the mesh cover layer 211, as illustrated in FIG. 7, and the ink I may be transferred onto the cover glass 120 through the printing opening 212, thereby forming the light-shielding printed pattern 122, as illustrated in FIG. 3.

The mesh cover layer 211 may be a coating layer applied to cover the entirety of the mesh member 213, except for the printing opening 212. In this case, the mesh cover layer 211 fills all the pores of the mesh member 213 except for the part exposed by the printing opening 212.

The mesh cover layer 211 may include or consist of a photosensitive resin. In an embodiment, the photosensitive resin may include polyvinyl alcohol (“PVA”), PVA acetate (“PVAc”), silicone resin, acrylic resin, or epoxy resin, for example, but the disclosure is not limited thereto.

When the mesh cover layer 211 includes or consists of a photosensitive resin, the printing opening 212 may be formed by exposure using a photomask for forming the printing opening 212. Here, the printing opening 212, where the photosensitive resin is absent, allows the ink I to be transferred to the substrate 100 through the pores in the mesh member 213, while the ink I disposed on the mesh cover layer 211 does not pass through the mesh member 213, forming the non-printing area.

The ink I may be placed on an upper surface 211a of the mesh cover layer 211, and printing may be performed by moving the squeegee member 24 over the mesh cover layer 211. By pressing the ink I with the squeegee member 24, the ink I passes through the exposed part of the mesh member 213 via the printing opening 212, the light-shielding printed pattern 122 may be printed on the substrate 100 in accordance with the shape of the printing opening 212. The mesh member 213 may move toward the substrate 100 with the force applied by the squeegee member 24.

Referring to FIGS. 6A to 7, the tension adjusting member 220 may be disposed on a lower surface 211b of the mesh cover layer 211 near the printing opening 212.

The tension adjusting member 220 may precisely control the tension of the mesh member 213 by adjusting the pressure exerted by the squeegee member 24 on the mesh member 213 of the printing mask (211 and 213) during printing.

The tension adjusting member 220 may provide tension to the mesh member 213 of the printing mask (211 and 213) and may create a step difference. The tension adjusting member 220 may have various forms. In an embodiment, the tension adjusting member 220 may be formed as an adhesive tape or as a resin layer on the lower surface 211b of the mesh cover layer 211 near the printing opening 212, or by making the mesh cover layer 211 of the printing mask (211 and 213) thicker to create a step difference, for example. In another embodiment, a SUS mesh with a quadrangular, e.g., rectangular plate shape may be attached to the mounting position of the tension adjusting member 220, in which case, a polyester mesh may be additionally attached onto the entirety of the SUS mesh except for the printing opening 212.

When the tension adjusting member 220 is formed as a resin layer on the lower surface 211b of the mesh cover layer 211, the tension adjusting member 220 may include or consist of a material such as polyethylene (“PE”), polyvinyl chloride (“PVC”), polystyrene (“PS”), polyester film (“PET”), or polypropylene (“PP”), but the disclosure is not limited thereto.

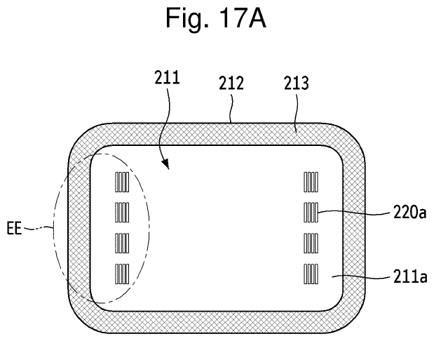

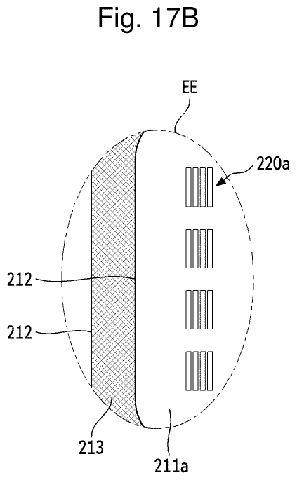

When the tension adjusting member 220 is provided in the form of an adhesive tape, the tension adjusting member 220 may have a single strip shape corresponding to the printing opening 212, but the disclosure is not limited thereto. As will be described later with reference to FIGS. 17A and 17B, the tension adjusting member 220 may be provided in the form of multiple segmented tape forms, but the disclosure is not limited thereto. The material of the tension adjusting member 220 may be any type of adhesive tape that may provide durability and adhesion.

The tension adjusting member 220 may have the same shape as that of the printing opening 212, but the disclosure is not limited thereto. In an embodiment, the tension adjusting member 220 may have an empty quadrangular frame shape, e.g., rectangular frame shape, a polygonal shape, a circular shape, or an elliptical shape.

The width of the tension adjusting member 220 may be the same as or greater than the width of the printing opening 212, but the disclosure is not limited thereto. The size of the tension adjusting member 220 may be smaller than the size of the printing opening 212 so that the tension adjusting member 220 may be disposed within the printing opening 212. The shape of the tension adjusting member 220 is not limited as long as the tension adjusting member 220 may be disposed within a print end area that will be described later.

As the tension adjusting member 220 is disposed on the lower surface 211b of the mesh cover layer 211, forming a tension-adjusting step difference structure, fine-tuning precision may be achieved through the step difference created by the tension adjusting member 220. Specifically, during printing, as the squeegee member 24 moves in the direction of the arrow in FIG. 8 near the printing opening 212, the tension adjusting member 220 may provide tension to the printing mask (211 and 213) at the print end area of the printing opening 212, allowing the squeegee member 24 to move upward as it exits from the entry area of the printing opening 212 to the print end area of the printing opening 212.

Additionally, as the tension adjusting member 220 is disposed on the rear side of the screen mask unit 200, the formation of a defective shape, such as a saw-tooth pattern, in the light-shielding printed pattern 122 may be suppressed by preventing the ink I from seeping through natural gaps in the mesh cover layer 211.

Accordingly, the screen printing device 1 may increase tension, specifically in areas adjacent to the printing opening 212 where the light-shielding printed pattern 122 is formed, may minimize the impact of the mesh shape through a step difference and may provide precise tuning of the tension through the step difference formation of the tension adjusting member 220.

The process of printing the light-shielding printed pattern 122 will hereinafter be described with reference to FIGS. 8 through 12.

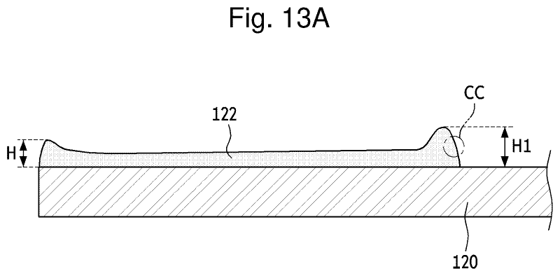

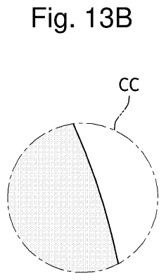

Referring to FIG. 8, which illustrates the state where the squeegee member 24 is disposed in the area of the printing opening 212 of the screen mask unit 200, when the scraper 23 applies the ink I onto the screen mask unit 200, the squeegee member 24 moves along the arrow's direction, pushing the ink I into the printing opening 212 of the screen mask unit 200. Then, the ink I may be transferred to the substrate 100 disposed under the screen mask unit 200, forming the light-shielding printed pattern 122 with the same width as the printing opening 212, as illustrated in FIGS. 13A and 13B.

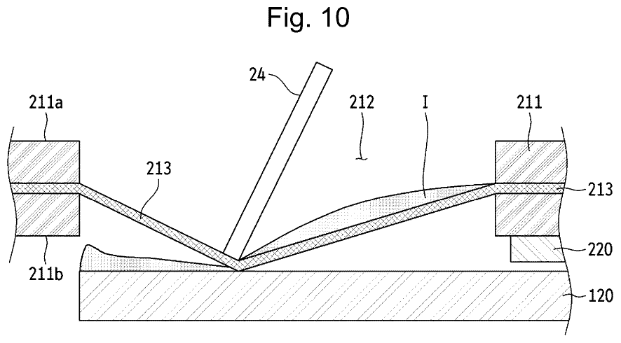

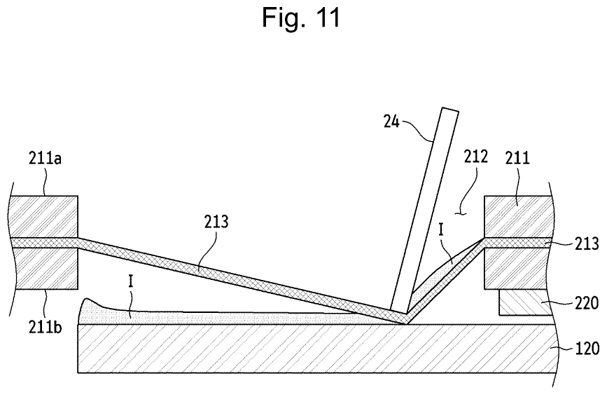

Specifically, as illustrated in FIG. 9, the squeegee member 24 is disposed at one side of the cover glass 120, which is the printing target, with a part of the mesh member 213 exposed by the printing opening 212. With the ink I on the mesh member 213, the squeegee member 24 moves along the printing direction. Referring to FIGS. 10 and 11, as the squeegee member 24 moves, the squeegee member 24 may press the mesh member 213, causing the mesh member 213 to contact the substrate 100. At this moment, as illustrated in FIG. 11, the ink I on the mesh member 213 may be transferred to the substrate 100 through the printing opening 212, forming the light-shielding printed pattern 122. As the squeegee member 24 starts from the initial position of the printing opening 212 and pushes the ink I onto the substrate 100, the squeegee member 24 eventually exits the printing opening 212. At the moment the squeegee member 24 reaches the print end area of the printing opening 212, where the tension adjusting member 220 is attached, the tension of the printing mask (211 and 213) increases. The squeegee member 24 moves upward as it exits the printing opening 212 due to the increased tension, allowing it to leave the printing opening 212. As the squeegee member 24 moves upward, as illustrated in FIGS. 13A and 13B, a height H1 of the light-shielding printed pattern 122 at the print end area may be greater than a height H of the light-shielding printed pattern 122 at the print start area. Additionally, as ink I is prevented from entering the gap between the substrate 100 and the screen mask unit 200, defects in the final light-shielding printed pattern 122 may be prevented.

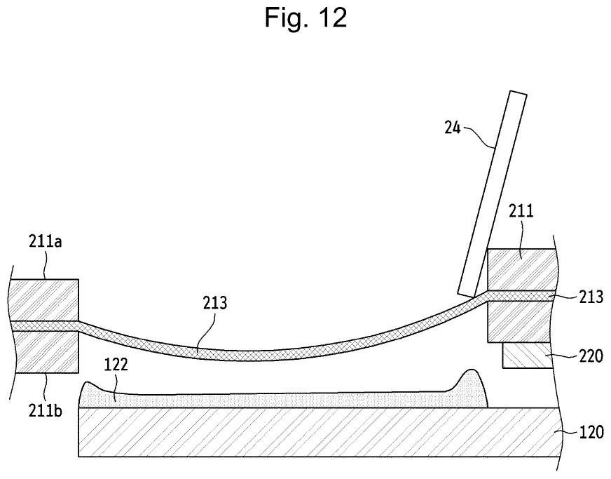

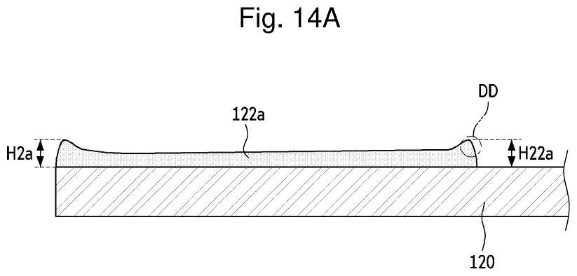

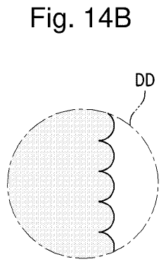

FIG. 13A is an enlarged view of the light-shielding printed pattern of FIG. 12, FIG. 13B is an enlarged view of portion CC of FIG. 13A, FIG. 14A is an enlarged view of a light-shielding printed pattern printed with a screen mask unit without a tension adjusting member, and FIG. 14B is an enlarged view of portion DD of FIG. 14A.

Referring to FIGS. 13A to 14B, as the tension adjusting member 220 is disposed, one side of the light-shielding printed pattern 122 may exhibit a uniform shape, as illustrated in FIGS. 13A and 13B. As the squeegee member 24 moves upward and exits the printing opening 212, the height H1 on the right side may be greater than the height H on the left side, as illustrated in FIGS. 13A and 13B. However, when the tension adjusting member 220 is not present, a saw-tooth pattern defect may occur in the light-shielding printed pattern 122a, as illustrated in FIGS. 14A and 14B, and heights H2a and H22a of the light-shielding printed pattern 122a on the left and right sides, respectively, may be equal.

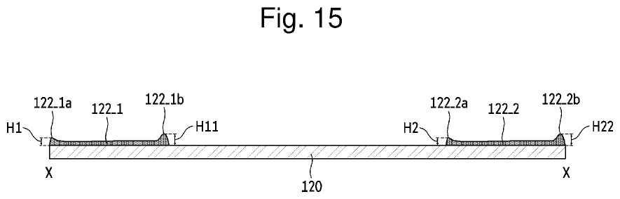

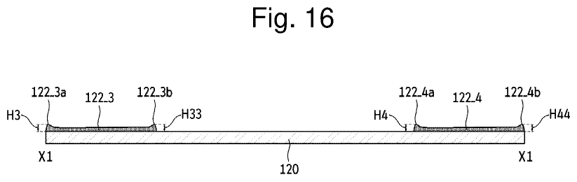

FIG. 15 is a cross-sectional view of the light-shielding printed pattern and substrate along line X-X of FIG. 3, and FIG. 16 is a cross-sectional view of the light-shielding printed pattern and substrate along line X1-X1 of FIG. 3.

Referring to FIG. 15, the light-shielding printed pattern 122, fabricated by the screen mask unit 200 at positions where the tension adjusting member 220 is attached, may include, e.g., a pair of light-shielding printed pattern parts disposed at the short sides of the cover glass 120, i.e., first and second pattern parts 122_1 and 122_2.

The first and second pattern parts 122_1 and 122_2 may be spaced apart from each other in a first direction, i.e., the Y-axis direction, and may be disposed at the short sides of the cover glass 120.

The first and second pattern parts 122_1 and 122_2 may include first pattern edges 122_1a and 122_2a, respectively, which extend in the Y-axis direction, and second pattern edges 122_1b and 122_2b, which extend in the Y-axis direction and face the first pattern edges 122_1a and 122_2a.

The second pattern edges 122_1b and 122_2b may be parts of the light-shielding printed pattern 122 formed at the positions where the tension adjusting member 220 is attached, and heights H11 and H22 of the second pattern edges 122_1b and 122_2b may be greater than heights H1 and H2 of the first pattern edges 122_1a and 122_2a, which are formed at positions where the tension adjusting member 220 is not attached.

Referring to FIG. 16, the light-shielding printed pattern 122, fabricated by the screen mask unit 200 at the positions where the tension adjusting member 220 is not attached, includes, e.g., a pair of light-shielding printed pattern parts disposed at the long sides of the cover glass 120, i.e., third and fourth pattern parts 122_3 and 122_4.

The third and fourth pattern parts 122_3 and 122_4 may be spaced apart from each other in a second direction, i.e., the X-axis direction, and may be disposed at the long sides of the cover glass 120.

The third and fourth pattern parts 122_3 and 122_4 extend in a second direction, i.e., the X-axis direction, and include third pattern edges 122_3a and 122_4a, respectively, and fourth pattern edges 122_3b and 122_4b, respectively, which face the third pattern edges 122_3a and 122_4a.

The third pattern edges 122_3a and 122_4a and the fourth pattern edges 122_3b and 122_4b may both be parts of the light-shielding pattern 122 formed at the positions where the tension adjusting member 220 is not attached, and heights H33 and H44 of the fourth pattern edges 122_3b and 122_4b may be the same as heights H3 and H4 of the third pattern edges 122_3a and 122_4a.

Other embodiments of the disclosure will hereinafter be described with reference to FIGS. 17A through 24.

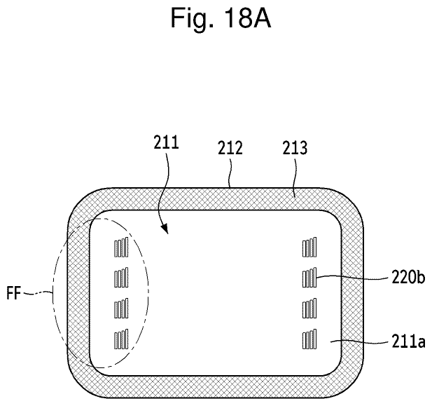

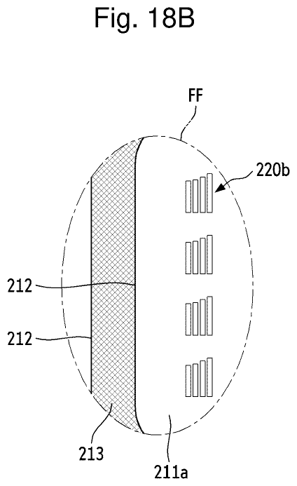

FIGS. 17A and 18A illustrate tension adjusting members according to other embodiments of the disclosure. FIG. 17B is an enlarged view of portion EE of FIG. 17A, and FIG. 18B is an enlarged view of portion FF of FIG. 18A.

The embodiment of FIGS. 17A and 17B differs from the embodiment of FIGS. 6A and 6B in that tension adjusting members 220a, which are attached to a lower surface 211b of a mesh cover layer 211, are in a segmented tape form.

Referring to FIGS. 17A and 17B, the tension adjusting members 220a may be in a segmented tape form that creates a step difference structure for tension adjustment, and may provide fine-tuning precision through this step difference structure. In this manner, the tension adjusting members 220a may provide a structure for forming a step difference on the lower surface 211b of the mesh cover layer 211, enabling precise tuning.

When the tension adjusting members 220a are in a segmented tape form, tension may be adjusted according to the thickness and the number of tension adjusting member 220a. Additionally, for precise tuning, tension may be adjusted by removing or adding the tension adjusting members 220a at points where tension adjustment is desired. This allows for simplified work and quantification during fine-tuning at each point without moving all the tension adjusting members 220a. In an embodiment, in a case where tension evaluation needs to be conducted with all tension adjusting members 220a attached and then tension needs to be set differently for different areas of a mesh member 213 of a printing mask (211 and 213), the tension may be finely adjusted by removing the tension adjusting members 220a according to the desired tension value for each area of the mesh member 213 of the printing mask (211 and 213), for example. Depending on conditions such as the pressure of a squeegee member 24 and the thickness of the mesh cover layer 211, the tension may be finely adjusted by removing or adding multiple tension adjusting members 220a. Also, the tension may be adjusted for each area by varying the thickness and shape of the multiple tension adjusting members 220a. However, the disclosure is not limited to these examples, and there may be various other methods for fine-tuning the tension.

The embodiment of FIGS. 18A and 18B differs from the embodiment of FIGS. 17A and 17B in that a plurality of sets of tension adjusting members 220b, which are attached to a lower surface 211b of a mesh cover layer 211, have varying heights.

Referring to FIGS. 18A and 18B, each set of tension adjusting members 220b may be arranged to gradually increase in height, forming an ascending curve from the first tension adjusting member 220b to the last tension adjusting member 220b. Unlike in the embodiment of FIGS. 17A and 17B where all the tension adjusting members 220a have the same size, in the embodiment of FIGS. 18A and 18B, the tension adjusting members 220b have different heights so that different tension strengths may be provided. By removing or adding the tension adjusting members 220b in various combinations, finer tension adjustment may be achieved.

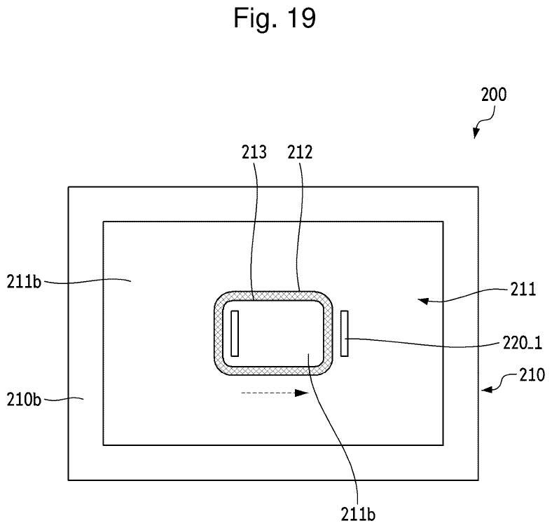

FIGS. 19 through 24 illustrate various exemplary tension adjusting members 220.

The embodiment of FIG. 19 differs from the embodiment of FIGS. 6A and 6B in that tension adjusting members 220_1 are disposed discontinuously in a short-side direction.

Referring to FIG. 19, unlike the tension adjusting member 220 of FIGS. 6A and 6B, which is continuously connected, the tension adjusting members 220_1 may be disposed discontinuously. Since a squeegee member 24 moves from a print initial position where the printing of a light-shielding printed pattern 122 begins to a print end position where the squeegee member 24 exits a printing opening 212, the tension adjusting members 220_1 may be arranged as a pair only at the print end position.

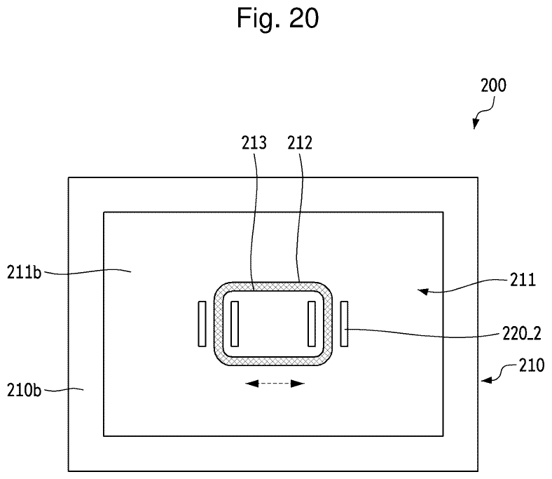

Referring to FIG. 20, tension adjusting members 220_2 may be disposed discontinuously. However, unlike the tension adjusting members 220_1 of FIG. 19, the tension adjusting members 220_2 may be arranged both at the print start position and the print end position around the printing opening 212, along the arrow's direction.

Specifically, in the embodiment of FIG. 19, the tension adjusting members 220_1 may be disposed only at the print end position, but in the embodiment of FIG. 20, two pairs of tension adjusting members 220_2 may be arranged at a total of four locations in the short-side direction around the printing opening 212.

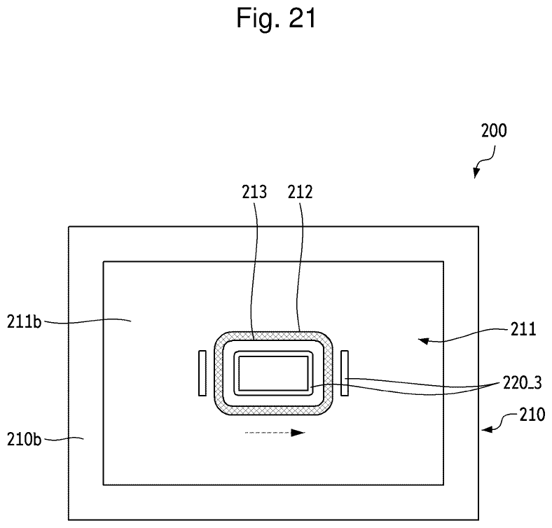

The embodiment of FIG. 21 differs from the embodiment of FIGS. 6A and 6B in that in addition to a quadrangular loop-shaped tension adjusting member, e.g., rectangular loop-shaped tension adjusting member 220_3, which is in the same shape as its counterpart of FIGS. 6A and 6B, additional tension adjusting members 220_3 are further provided.

Referring to FIG. 21, the quadrangular loop-shaped tension adjusting member, e.g., rectangular loop-shaped tension adjusting member 220_3 may be disposed along the printing opening 212, and a pair of additional tension adjusting members 220_3 may be disposed on sides, in the short-side direction, of the printing opening 212 along the movement direction of the squeegee member 24.

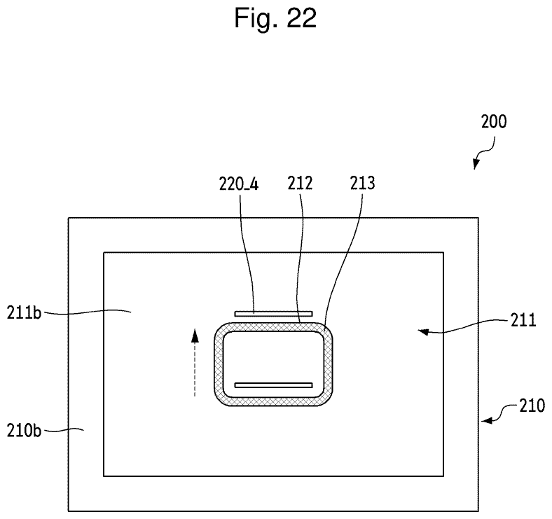

The embodiment of FIG. 22 differs from the embodiment of FIG. 19 in that tension adjusting members 220_4 are disposed discontinuously in a long-side direction around the printing opening 212.

In the embodiment of FIG. 22, unlike in the embodiment of FIG. 19 where a pair of tension adjusting members 220_1 are disposed discontinuously in the short-side direction, pairs of tension adjusting members 220_4 may be disposed along the arrow direction inside or outside the printing opening 212.

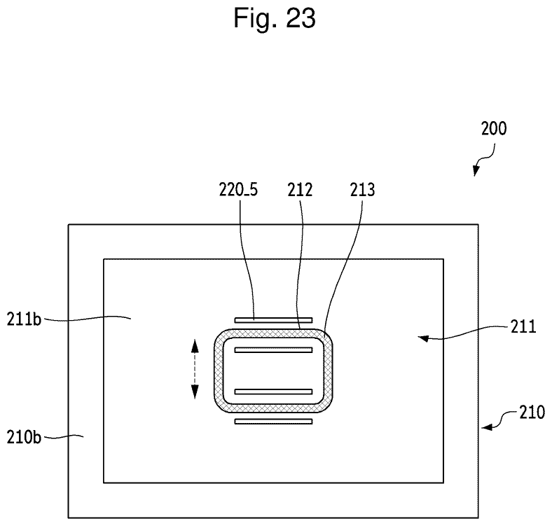

The embodiment of FIG. 23 differs from the embodiment of FIG. 22 in that tension adjusting members 220_5 are disposed discontinuously both at a print start position and a print end position around the printing opening 212 along the long-side direction.

Specifically, in the embodiment of FIG. 22, the tension adjusting members 220_4 may be disposed only at the print end position when the squeegee member 24 moves in the arrow's direction, but in the embodiment of FIG. 23, two pairs of tension adjusting members 220_5 may be arranged at a total of four locations in the long-side direction around the printing opening 212.

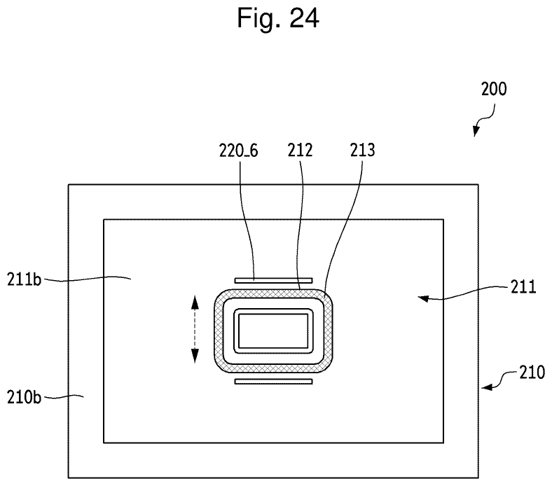

The embodiment of FIG. 24 differs from the embodiment of FIGS. 6A and 6B in that, in addition to a quadrangular loop-shaped tension adjusting member, e.g., rectangular loop-shaped tension adjusting member 220_6, which is in the same shape as its counterpart of FIGS. 6A and 6B, a pair of additional tension adjusting members 220_6 are further provided.

Referring to FIG. 24, a pair of additional tension adjusting members 220_6 may be further provided along the long-side direction, i.e., the movement direction of the squeegee member 24, and the loop-shaped tension adjusting member 220 of FIG. 6 may be arranged between the additional tension adjusting members 220_6 around the circumferential direction of the printing opening 212.

As described, as the tension adjusting members 220 are provided on the lower surface 211b of the mesh cover layer 211 of the screen mask unit 200, an asymmetric step difference and tension structure may be provided to the screen mask unit 200. This may prevent defects such as a saw-tooth pattern from occurring in the light-shielding printed pattern 122 and may thereby improve printing precision, stability, and reliability.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A screen printing device comprising:
a substrate support unit;
a squeegee member above the substrate support unit;
a screen mask unit disposed between the substrate support unit and the squeegee member, the screen mask unit defining a printing opening which forms a printed pattern; and
at least one tension adjusting member disposed on a first surface of the screen mask unit facing the substrate support unit and adjacent to the printing opening.

2. The screen printing device of claim 1, wherein the at least one tension adjusting member is provided in plural, and
a plurality of tension adjusting members forms a group, creating multiple rows.

3. The screen printing device of claim 2, wherein
the plurality of tension adjusting members is arranged in the multiple rows, and
multiple tension adjusting members arranged in one row among the plurality of tension adjusting members respectively have sizes equal to each other.

4. The screen printing device of claim 1, wherein
the at least one tension adjusting member and the printing opening each have a rectangular frame shape, and
the at least one tension adjusting member is smaller in size than the printing opening and overlaps an inside the printing opening.

5. The screen printing device of claim 1, wherein a height of the at least one tension adjusting member along a thickness direction of the screen mask unit is smaller than a height of the printing opening.

6. The screen printing device of claim 1, wherein
the screen mask unit includes a mesh member, which is porous, and a mesh cover layer, which covers the mesh member, and
the mesh cover layer covers the mesh member but exposes a portion of the mesh member through the printing opening.

7. The screen printing device of claim 6, wherein the screen mask unit further includes a support frame, which supports edge areas of the mesh cover layer.

8. The screen printing device of claim 1, wherein
the substrate support unit supports a substrate so that substrate is disposed below the screen mask unit,
the substrate is a cover glass, and
the printed pattern printed through the printing opening of the screen mask unit is a light-shielding printed pattern disposed along edge areas of the cover glass.

9. The screen printing device of claim 8, further comprising:
a printing unit including the squeegee member, which transfers ink onto the substrate through the printing opening; and
a printing transfer unit which moves the printing unit.

10. A screen printing device comprising:
a substrate support unit;
a squeegee member above the substrate support unit;
a screen mask unit disposed between the substrate support unit and the squeegee member, the screen mask unit defining a printing opening for forming a printed pattern; and
at least one adhesive tape attached to a first surface of the screen mask unit facing the substrate support unit and adjacent to the printing opening.

11. The screen printing device of claim 10, wherein the at least one adhesive tape has a hollow rectangular frame shape.

12. The screen printing device of claim 10, wherein the at least one adhesive tape is disposed adjacent to the printing opening, and is attached along at least one area of the printing opening.

13. The screen printing device of claim 12, wherein
the at least one adhesive tape is provided in plural,
a plurality of adhesive tapes is disposed in multiple rows with a spacing therebetween, and
multiple adhesive tapes arranged in one row among the plurality of adhesive tapes respectively have sizes equal to each other.

14. The screen printing device of claim 10, wherein
the screen mask unit includes a mesh member, which is porous, and a mesh cover layer, which covers the mesh member, and
the mesh cover layer covers the mesh member but exposes a portion of the mesh member through the printing opening.

15. A transparent panel for a display device, the transparent panel comprising:
a substrate including:
first and second edges, which extend in a first direction and face each other; and
third and fourth edges, which extend in a second direction intersecting the first direction and face each other; and
a light-shielding printed pattern disposed on a periphery of the substrate, the light-shielding printed pattern including:
a first pattern part adjacent to the first edge of the substrate and a second pattern part adjacent to the second edge of the substrate,
wherein
the first and second pattern parts each extend in the first direction and include first and second pattern edges facing each other, and
the first pattern edge of the first pattern part and the second pattern edge of the first pattern part have different heights from each other.

16. The transparent panel of claim 15, wherein the first pattern edge of the second pattern part and the second pattern edge of the second pattern part have different heights from each other.

17. The transparent panel of claim 16, wherein
the second pattern edge of the first pattern part and the first pattern edge of the second pattern part are disposed inwardly of each pattern part and face each other,
the height of the second pattern edge of the first pattern part is greater than the height of the first pattern edge of the first pattern part, and
the height of the second pattern edge of the second pattern part is greater than the height of the first pattern edge of the second pattern part.

18. The transparent panel of claim 15, wherein the light-shielding printed pattern further includes a third pattern part adjacent to the third edge of the substrate and a fourth pattern part adjacent to the fourth edge of the substrate.

19. The transparent panel of claim 18, wherein
the third and fourth pattern parts each extend in the second direction and include third and fourth pattern edges facing each other, and
the third pattern edges of the third and fourth pattern parts each have a height identical to a height of each of the fourth pattern edges of the third and fourth pattern parts.

20. The transparent panel of claim 18, wherein the first pattern part, the third pattern part, the second pattern part, and the fourth pattern part are connected to one another and define a closed loop.
